(19) United States
(12) Patent Application Publication
(10) Pub. No.: US 2024/0121945 A1
(43) Pub. Date: Apr. 11, 2024

(54) SEMICONDUCTOR MEMORY DEVICE AND METHOD FOR FABRICATING THE SAME

(71) Applicant: Samsung Electronics Co., Ltd., Suwon-sI (KR)

(72) Inventors: Jin-Seong Lee, Suwon-si (KR); Tai Uk Rim, Suwon-si (KR); Ji Hun Kim, Suwon-si (KR); Kyo-Suk Chae, Suwon-si (KR)

(21) Appl. No.: 18/347,927

(22) Filed: Jul. 6, 2023

(30) Foreign Application Priority Data
Oct. 11, 2022 (KR) 10-2022-0129832
Mar. 7, 2023 (KR) 10-2023-0029851

(51) Int. Cl. H10B 12/00

(52) U.S. Cl. CPC H10B 12/34; H10B 12/053; H10B 12/315

(57) ABSTRACT

A semiconductor memory device comprises a substrate including a first source/drain region and a second source/drain region, a trench between the first source/drain region and the second source/drain region and formed in the substrate, a cell gate insulating layer on sidewalls and a bottom surface of the trench, a cell gate electrode on the cell gate insulating layer, a work function control pattern on the cell gate electrode, including N-type impurities and a cell gate capping pattern on the work function control pattern. The work function control pattern includes a semiconductor material. The work function control pattern includes a first region and a second region between the first region and the cell gate electrode. A concentration of the N-type impurities in the first region is greater than a concentration of the N-type impurities in the second region.

### CROSS-REFERENCE TO RELATED APPLICATIONS

This application is based on and claims priority under 35 U.S.C. § 119 to Korean Patent Application No. 10-2022-0129832 filed on Oct. 11, 2022, and Korean Patent Application No. 10-2023-0029851 filed on Mar. 7, 2023 in the Korean Intellectual Property Office, the disclosures of which are incorporated by reference herein in their entirety.

### BACKGROUND

The present disclosure relates generally to semiconductor memory devices and methods for fabricating the same.

As semiconductor devices become increasingly highly integrated, individual circuit patterns are becoming finer to implement more semiconductor devices in the same area. That is, with an increase in the desired degree of integration of semiconductor devices, the fabrication design rules for components of semiconductor devices have been reduced.

In highly scaled semiconductor devices, a process of forming a plurality of wiring lines and a plurality of buried contacts (BC) interposed between the wiring lines has become increasingly complex and difficult.

### BRIEF SUMMARY

An object of the present disclosure is to provide a semiconductor memory device that may improve reliability and performance.

Another object of the present disclosure is to provide a method for fabricating a semiconductor memory device that may improve reliability and performance.

Objects of the present disclosure are not limited to those mentioned above and additional objects of the present disclosure, which are not mentioned herein, will be clearly understood by those skilled in the art from the following description of the present disclosure.

According to some embodiments of the present disclosure, there is provided a semiconductor memory device comprising a substrate including a first source/drain region and a second source/drain region, a trench disposed between the first source/drain region and the second source/drain region and formed in the substrate, a cell gate insulating layer on at least a portion of sidewalls and a bottom surface of the trench, a cell gate electrode on the cell gate insulating layer, a work function control pattern on the cell gate electrode, including N-type impurities and a cell gate capping pattern on the work function control pattern, wherein the work function control pattern includes a semiconductor material, the work function control pattern includes a first region and a second region between the first region and the cell gate electrode, and a concentration of the N-type impurities in the first region is greater than that of the N-type impurities in the second region.

According to some embodiments of the present disclosure, there is provided a semiconductor memory device comprising a substrate including an active region defined by an element isolation layer, a bit line extending in a first direction on the substrate, an information storage element (i.e., storage structure) disposed at both sides of the bit line and connected to the active region; and a cell gate structure extending in a second direction crossing the first direction and formed in the substrate, wherein the cell gate structure includes a trench formed in the substrate, a cell gate insulating layer on at least a portion of sidewalls and a bottom surface of the trench, a cell gate electrode on the cell gate insulating layer, a barrier layer on the cell gate electrode and a work function control pattern on the barrier layer, including a semiconductor material, and the work function control pattern includes a first region including N-type impurities, and a second region disposed between the first region and the cell gate electrode.

According to some embodiments of the present disclosure, there is provided a semiconductor memory device comprising a substrate including an active region defined by an element isolation layer and extending in a first direction, the active region including a first portion and a second portion defined at both sides of the first portion, a cell gate structure extending in a second direction in the substrate and the element isolation layer, crossing between the first portion of the active region and the second portion of the active region, a bit line extending in a third direction on the substrate and the element isolation layer and connected to the first portion of the active region, a storage contact disposed at both sides of the bit line and connected to the second portion of the active region, a storage pad connected to and disposed on the storage contact and a capacitor connected to and disposed on the storage pad, wherein the cell gate structure includes a trench formed in the substrate, a cell gate insulating layer on at least a portion of sidewalls and a bottom surface of the trench, a cell gate electrode on the cell gate insulating layer, a work function control pattern on the cell gate electrode, including N-type impurities, a cell gate capping pattern on the work function control pattern, the work function control pattern including a semiconductor material, the work function control pattern includes a first region and a second region between the first region and the cell gate electrode and a concentration of the N-type impurities in the first region is greater than that of the N-type impurities in the second region.

According to some embodiments of the present disclosure, there is provided a method for fabricating a semiconductor memory device comprising providing a substrate including an active region defined by an element isolation layer, forming a trench extending in a first direction in the substrate and the element isolation layer, forming a cell gate insulating layer on sidewalls and a bottom surface of the trench, forming a cell gate electrode on the cell gate insulating layer, forming a pre-work function control pattern including a semiconductor material on the cell gate electrode, forming a work function control pattern by doping the pre-work function control pattern with N-type impurities and forming a cell gate capping layer on the work function control pattern, wherein the work function control pattern includes a first region and a second region between the first region and the cell gate electrode, and a concentration of the N-type impurities in the first region is greater than that of the N-type impurities in the second region.

### BRIEF DESCRIPTION OF THE DRAWINGS

The above and other aspects and features of the present disclosure will become more apparent by describing in detail exemplary embodiments thereof with reference to the attached drawings, wherein like reference numerals (when used) indicate corresponding elements throughout the several views, and in which:

FIG. 1 is a schematic layout illustrating at least a portion of an exemplary semiconductor memory device, according to some embodiments.

FIG. 2 is a layout illustrating only a word line and an active region of the exemplary semiconductor memory device shown in FIG. 1.

FIG. 3 is an exemplary cross-sectional view depicting at least a portion of the semiconductor memory device shown in FIG. 1 taken along line A-A of FIG. 1.

FIG. 4 is an exemplary cross-sectional view depicting at least a portion of the semiconductor memory device shown in FIG. 1 taken along line B-B of FIG. 1.

FIG. 5 is an exemplary cross-sectional view depicting at least a portion of the semiconductor memory device shown in FIG. 1 taken along line C-C of FIG. 1.

FIG. 6 is an exemplary cross-sectional view depicting at least a portion of the semiconductor memory device shown in FIG. 1 taken along line D-D of FIG. 1.

FIG. 7 is an enlarged view illustrating a portion P of the exemplary semiconductor memory device shown in FIG. 6.

FIGS. 8 and 9 are views graphically illustrating a concentration of N-type impurities along SCAN LINE of FIG. 7.

FIGS. 10 and 11 are views graphically illustrating a concentration of carbon along SCAN LINE of FIG. 7.

FIG. 12 is a view graphically illustrating a concentration of P-type impurities along SCAN LINE of FIG. 7.

FIG. 13 is a cross-sectional view illustrating at least a portion of an exemplary semiconductor memory device, according to some embodiments.

FIG. 14 to 19 are views illustrating intermediate steps to describe an exemplary method for fabricating a semiconductor memory device, according to some embodiments.

### DETAILED DESCRIPTION OF THE DISCLOSURE

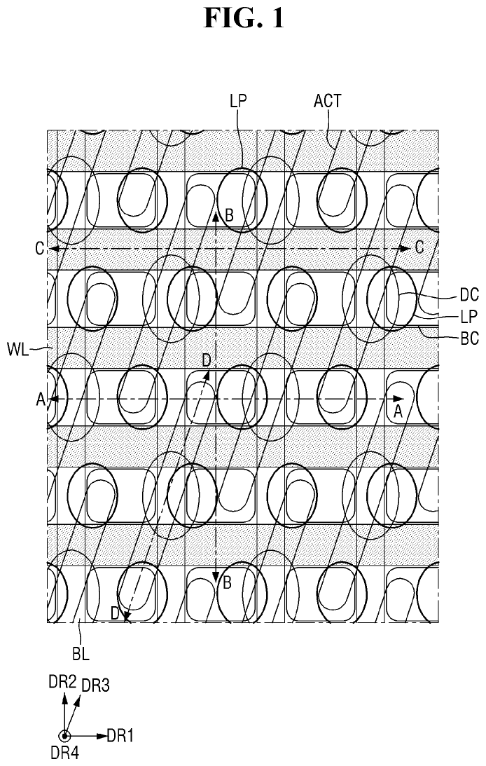

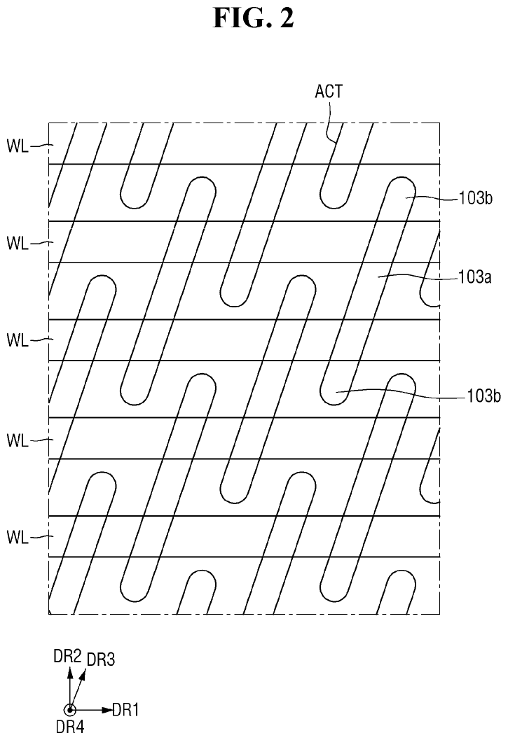

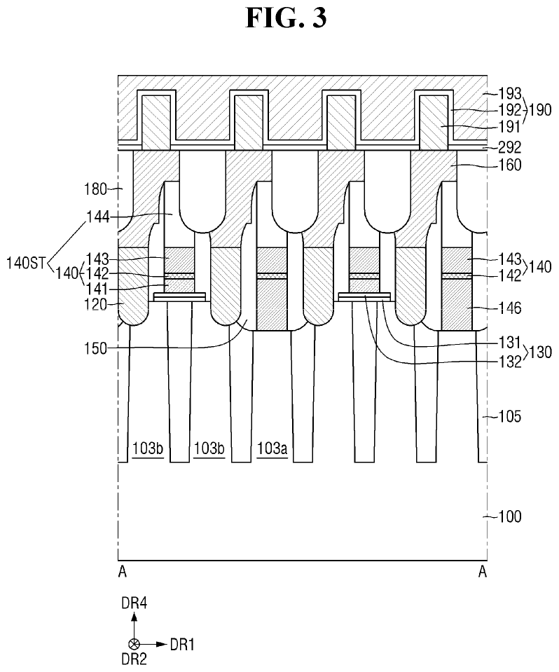

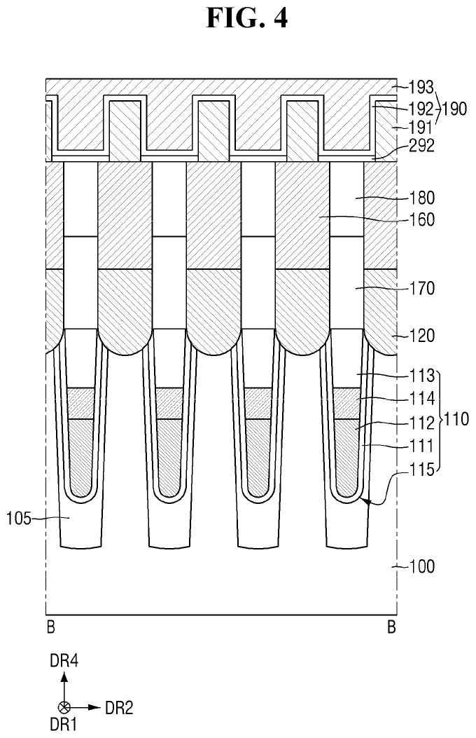

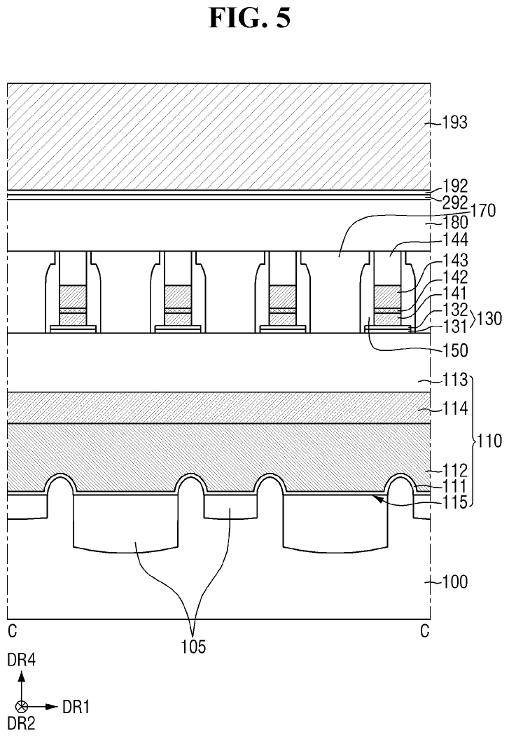

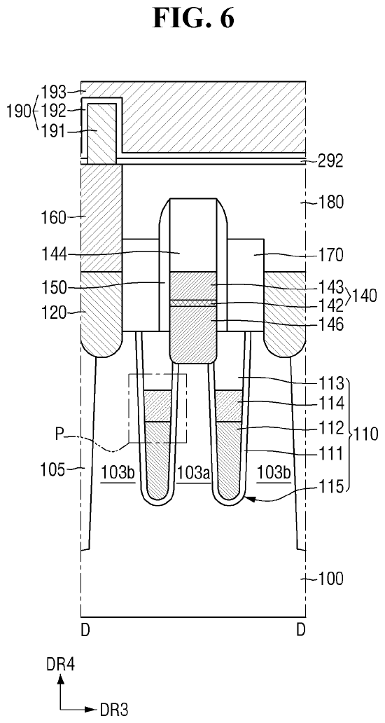

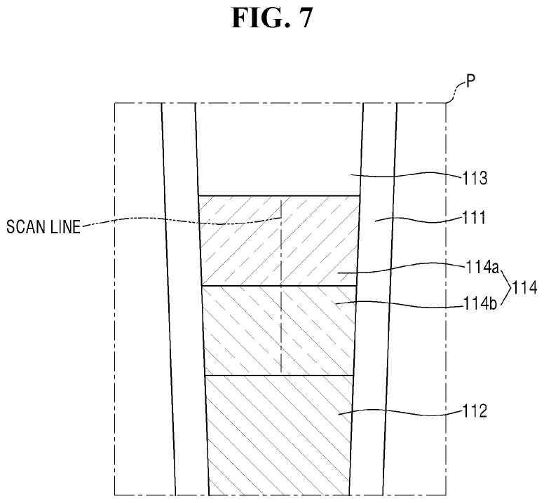

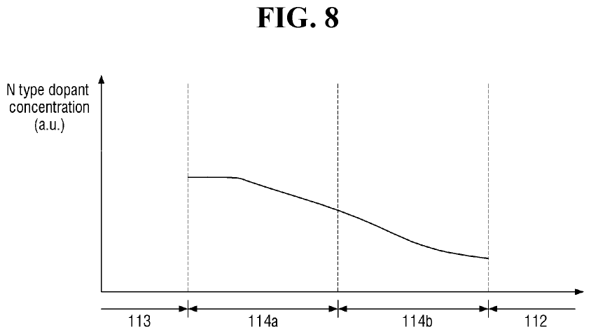

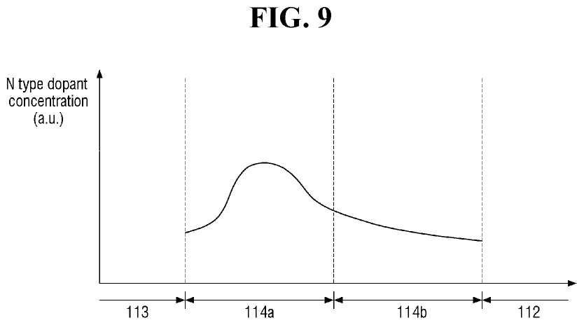

FIG. 1 is a schematic layout illustrating at least a portion of an exemplary semiconductor memory device according to some embodiments. FIG. 2 is a layout illustrating only a word line and an active region of the exemplary semiconductor memory device shown in FIG. 1. FIG. 3 is an exemplary cross-sectional view depicting at least a portion of the semiconductor memory device shown in FIG. 1 taken along line A-A of FIG. 1. FIG. 4 is an exemplary cross-sectional view depicting at least a portion of the semiconductor memory device shown in FIG. 1 taken along line B-B of FIG. 1. FIG. 5 is an exemplary cross-sectional view depicting at least a portion of the semiconductor memory device shown in FIG. 1 taken along line C-C of FIG. 1. FIG. 6 is an exemplary cross-sectional view depicting at least a portion of the semiconductor memory device shown in FIG. 1 taken along line D-D of FIG. 1. FIG. 7 is an enlarged view illustrating a portion P of FIG. 6. FIGS. 8 and 9 are views graphically illustrating a concentration of N-type impurities along a line SCAN LINE of FIG. 7.

Although a dynamic random-access memory (DRAM) may be shown in the drawings related to a semiconductor memory device according to some embodiments by way of example, the present disclosure is not limited thereto.

Referring to FIGS. 1 and 2, the semiconductor memory device according to some embodiments may include a plurality of cell active regions ACT.

The cell active region ACT may be defined by a cell element isolation layer (105 of FIGS. 3 and 4) formed in a substrate (100 of FIGS. 3 and 4). As a design rule of the semiconductor memory device is reduced (i.e., scaled), the cell active region ACT may be disposed in a bar shape of a diagonal line or an oblique line (i.e., less than 90 degrees relative to directions DR1 or DR2). For example, the cell active region ACT may extend in a third direction DR3.

A plurality of gate electrodes may be disposed in a first direction DR1 (e.g., horizontal) across the cell active region ACT. The plurality of gate electrodes may extend in parallel with each other. The plurality of gate electrodes may be, for example, a plurality of word lines WL. In some embodiments, the word lines WL may be disposed at regular intervals. A width of the word line WL or an interval between the word lines WL may be determined in accordance with the design rule.

Each cell active region ACT may be divided into three portions by two adjacent word lines WL extending in the first direction DR1. The cell active region ACT may include a storage connection portion 103b and a bit line connection portion 103a. The bit line connection portion 103a may be positioned at a center portion of the cell active region ACT, and the storage connection portion 103b may be positioned at an end of the cell active region ACT.

For example, the bit line connection portion 103a may be an area connected to a bit line BL, and the storage connection portion 103b may be an area connected to an information storage element or structure (e.g., 190 of FIG. 3). In other words, the bit line connection portion 103a may correspond to a common drain region, and the storage connection portion 103b may correspond to a source region. Each word line WL, the bit line connection portion 103a adjacent thereto, and the storage connection portion 103b may constitute a transistor.

A plurality of bit lines BL extending in a second direction DR2 (e.g., vertical) orthogonal to the first direction DR1 in which the word lines WL extend, may be disposed on the word line WL. The plurality of bit lines BL may extend in parallel with each other. The bit lines BL may be disposed at regular intervals. A width of the bit line BL or an interval between the bit lines BL may be determined in accordance with the design rule.

A fourth direction DR4 may be orthogonal to the first direction DR1, the second direction DR2, and the third direction DR3. The fourth direction DR4 may be a thickness direction of the substrate (100 of FIGS. 3 and 4).

The semiconductor memory device according to some embodiments may include various contact arrangements formed on the cell active region ACT. The various contact arrangements may include, for example, a direct contact DC, a buried contact BC, a landing pad LP, and the like.

The direct contact DC may refer to a contact that electrically connects the cell active region to the bit line BL. The buried contact BC may refer to a contact that connects the cell active region ACT to a lower electrode (191 of FIG. 3) of a capacitor. A contact area between the buried contact BC and the cell active region ACT may be small in view of an arrangement structure. Therefore, a conductive landing pad LP may be introduced to enlarge the contact area with the lower electrode (191 of FIG. 3) of the capacitor together with the contact area with the cell active region ACT.

The landing pad LP may be disposed between the cell active region ACT and the buried contact BC, and may be disposed between the buried contact BC and the lower electrode (191 of FIG. 4) of the capacitor. In the semiconductor memory device according to some embodiments, the landing pad LP may be disposed between the buried contact BC and the lower electrode of the capacitor. As the contact area is enlarged through the introduction of the landing pad LP, contact resistance between the cell active region ACT and the lower electrode of the capacitor may be reduced.

The direct contact DC may be connected to the bit line connection portion 103a. The buried contact BC may be connected to the storage connection portion 103b. As the buried contact BC may be disposed at both end portions of the cell active region ACT, the landing pad LP may partially overlap the buried contact BC in a state that it is adjacent to both ends of the cell active region ACT. In other words, the buried contact BC may overlap the cell active region ACT and the cell element isolation layer (105 of FIGS. 3 and 4) between adjacent word lines WL and between adjacent bit lines BL.

The word line WL may be formed in a structure buried in the substrate (100 of FIGS. 3 and 4). The word line WL may be disposed across the cell active region ACT between the direct contacts DC or the buried contacts BC. As shown, two adjacent word lines WL may cross one cell active region ACT. As the cell active region ACT extends in the third direction DR3, the word line WL may have an angle less than 900 with respect to the cell active region ACT.

The direct contact DC and the buried contact BC may be symmetrically disposed.

For this reason, the direct contact DC and the buried contact BC may be disposed on a straight line along the first direction DR1 and the second direction DR2. Unlike the direct contact DC and the buried contact BC, the landing pad LP may be disposed in a zigzag shape in the second direction DR2 in which the bit line BL extends. In addition, the landing pad LP may overlap the same side portion of each bit line BL in the first direction DR1 in which the word line WL extends.

For example, each landing pad LP of a first line may overlap a left side of a corresponding bit line BL, and each landing pad LP of a second line may overlap a right side of a corresponding bit line BL.

Referring to FIGS. 1 to 7, the semiconductor memory device according to some embodiments may include a plurality of cell gate structures 110, a plurality of bit line structures 140ST, a plurality of bit line contacts 146, and an information storage element 190.

The substrate 100 may be a silicon substrate or a silicon-on-insulator (SOI) substrate. Alternatively, the substrate 100 may include, but is not limited to, silicon germanium, silicon germanium on insulator (SGOI), indium antimonide, lead telluride compound, indium arsenide, indium phosphide, gallium arsenide or gallium antimonide.

The cell element isolation layer 105 may be formed in the substrate 100. The cell element isolation layer 105 may have a shallow trench isolation (STI) structure having excellent element isolation characteristics. The cell element isolation layer 105 may define the cell active region ACT in a memory cell region.

The cell active region ACT defined by the cell element isolation layer 105 may have a long island shape including a short axis and a long axis as shown in FIGS. 1 and 2. The cell active region ACT may have an oblique shape so as to extend (in the third direction DR3) at an angle less than 900 with respect to the word line WL formed in the cell element isolation layer 105. In addition, the cell active region ACT may have an oblique shape so as to extend at an angle less than 90° with respect to the bit line BL formed on the cell element isolation layer 105.

The cell element isolation layer 105 may include, but is not limited to, at least one of a silicon oxide layer, a silicon nitride layer and a silicon oxynitride layer. As used herein, the phrase “at least one of A, B and C” is intended to refer to element A alone, element B alone, element C alone, or any combination of two or more of elements A, B and C (e.g., A and B, B and C, or A and B and C).

The cell element isolation layer 105 is shown as being formed of one insulating layer, but this is only for convenience of description and is not limited thereto. The cell element isolation layer 105 may be formed of one insulating layer or a plurality of insulating layers depending on a distance at which the adjacent cell active regions ACT are spaced apart from each other.

In FIG. 3, although an upper surface of the cell element isolation layer 105 and an upper surface of the substrate 100 are shown as being disposed on the same plane (i.e., coplanar), it is only for convenience of description, and the present disclosure is not limited thereto. That is, a height (level) of the upper surface of the cell element isolation layer 105 shown in FIG. 3 may be different from (e.g., less than or greater than) a height of the upper surface of the cell element isolation layer 105 shown in FIG. 4, which may be due, at least in part, to the fabricating process.

The cell gate structure 110 may be formed in the substrate 100 and the cell element isolation layer 105. The cell gate structure 110 may be formed across the cell element isolation 105 and the cell active region ACT defined by the cell element isolation layer 105.

The cell gate structure 110 may include a cell gate trench 115, a cell gate insulating layer 111, a cell gate electrode 112, a cell gate capping pattern 113, and a work function control pattern 114.

In some embodiments, the cell gate electrode 112 may correspond to the word line WL. For example, the cell gate electrode 112 may be the word line WL shown in FIG. 1.

As shown in FIGS. 4 and 5, the cell gate trench 115 may be relatively deep in the cell element isolation layer 105, and may be relatively shallow in the cell active regions ACT. A bottom surface of the word line WL may be curved. That is, a depth of the cell gate trench 115 in the cell element isolation layer 105 may be greater than that of the cell gate trench 115 in the cell active region ACT.

The cell gate insulating layer 111 may extend along sidewalls and a bottom surface of the cell gate trench 115. That is, the cell gate insulating layer 111 may extend along a profile of at least a portion of the cell gate trench 115.

By way of example only and without limitation, the cell gate insulating layer 111 may include at least one of, for example, silicon oxide, silicon nitride, silicon oxynitride, and a high dielectric constant material having a dielectric constant higher than that of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate and any combination thereof.

The cell gate electrode 112 may be formed on at least a portion of the cell gate insulating layer 111. The cell gate electrode 112 may fill a portion of the cell gate trench 115. The term “fill” or “filled” as may be used herein is intended to refer broadly to either completely filling a defined space (e.g., cell gate trench 115) or partially filling the defined space; that is, the defined space need not be entirely filled but may, for example, be partially filled or have voids or other spaces throughout. The work function control pattern 114 may be disposed on at least a portion of an upper surface of the cell gate electrode 112.

The cell gate electrode 112 may include at least one of a metal, a metal alloy, a conductive metal nitride, a conductive metal carbonitride, a conductive metal carbide, a metal silicide, a doped semiconductor material, a conductive metal oxynitride and a conductive metal oxide. The cell gate electrode 112 may include at least one of, for example, TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and any combination thereof, but is not limited thereto. The following description will be made based on the assumption that the cell gate electrode 112 comprises TiN.

The work function control pattern 114 may be disposed on at least a portion of the cell gate electrode 112. In some embodiments, the work function control pattern 114 may cover at least a portion of the upper surface of the cell gate electrode 112. The work function control pattern 114 may overlap the cell gate electrode 112 in a fourth direction DR4. Both sidewalls of the work function control pattern 114 may be in contact with the cell gate insulation layer 111.

In some embodiments, the work function control pattern 114 may include a first region 114a and a second region 114b.

The first region 114a may be on at least a portion of the second region 114b. The second region 114b may be on at least a portion of the cell gate electrode 112. The second region 114b may be between the first region 114a and the cell gate electrode 112. A thickness of the first region 114a and a thickness of the second region 114b are the same as each other in the fourth direction DR4. The first region 114a may be defined as an upper portion of the work function control pattern 114. The second region 114b may be defined as a lower portion of the work function control pattern 114. A boundary between the first region 114a and the second region 114b may be in the middle of the work function control pattern 114 in the fourth direction DR4, depending on the respective thicknesses of the first and second regions 114a, 114b.

The boundary between the first region 114a and the second region 114b is shown as being distinguished, but is not limited thereto. Unlike the shown example, the boundary between the first region 114a and the second region 114b may not be distinguished. For example, the first and second regions 114a, 114b may be formed as a gradient, whereby a clearly define boundary between the respective regions is not present.

The work function control pattern 114 may include a semiconductor material. The semiconductor material of the work function control pattern 114 may include one of, for example, polysilicon, polysilicon-germanium, amorphous silicon, and amorphous silicon-germanium, but is not limited thereto. The following description will be made based on the assumption that the semiconductor material comprises polysilicon.

In some embodiments, the work function control pattern 114 may include impurities of a first conductivity type, such as, for example, N-type impurities; in some embodiments, impurities of a second conductivity type (opposite in polarity to the first conductivity type), such as, for example, P-type impurities, may be used. The N-type impurities may include at least one of phosphorus (P), arsenic (As), antimony (Sb), and bismuth (Bi), but are not limited thereto. A concentration of the N-type impurities in the first region 114a may be at least 1E20 (/cm³) or more. In this case, the concentration of the N-type impurities in the first region 114a may be an average concentration of the N-type impurities in the first region 114a. Hereinafter, the concentration of the N-type impurities of the work function control pattern 114 will be described in detail, according to one or more illustrative embodiments.

By way of example only and without limitation or loss of generality, each of the first region 114a and the second region 114b may include N-type impurities. The concentration (/cm³) of the N-type impurities in the first region 114a may be greater than that of the N-type impurities in the second region 114b.

Referring to FIG. 8, for example, the concentration of the N-type impurities of the work function control pattern 114 may be reduced as the work function control pattern 114 becomes farther away (in the fourth direction DR4) from the cell gate capping pattern 113. The concentration of the N-type impurities in the first region 114a may be reduced as the first region 114a becomes farther away from the cell gate capping pattern 113, and the concentration of the N-type impurities in the second region 114b may be reduced as the second region 114b becomes farther away from the first region 114a. The N-type impurities of the work function control pattern 114 may be formed, in some embodiments, by doping the semiconductor material with N-type impurities. The doping of the N-type impurities may involve a gas phase diffusion process, although embodiments of the inventive concept are not limited thereto.

Referring to FIG. 9, for another example, the concentration of N-type impurities in the first region 114a may be increased and then reduced as the first region 114a becomes farther away (in the fourth direction DR4) from the gate capping pattern 113. The concentration of the N-type impurities in the second region 114b may be reduced as the second region 114b becomes farther away from the first region 114a. In other words, the concentration of the N-type impurities in the work function control pattern 114 may be increased in the first region 114a to have a maximum value and then reduced as the work function control pattern 114 becomes farther away from the gate capping pattern 113. The N-type impurities of the work function control pattern 114 may be formed, in some embodiments, by doping the semiconductor material with N-type impurities. The doping of the semiconductor material using N-type impurities may involve an ion implantation process, although embodiments of the inventive concept are not limited thereto.

Unlike the shown example, the concentration of N-type impurities on a boundary surface between the second region 114b and the cell gate electrode 112 may be 0. That is, the concentration of the N-type impurities in the second region 114b may be reduced and then converged to 0 as the second region 114b becomes farther away from the first region 114a.

Referring back to FIGS. 7 to 9, the work function of the work function control pattern 114 may be smaller than that of the cell gate electrode 112. Since the concentration of the N-type impurities in the first region 114a of the work function control pattern 114 may be greater than that of the N-type impurities in the second region 114b, the work function of the first region 114a may be smaller than that of the second region 114b. The work function of the second region 114b may be smaller than that of the cell gate electrode 112. That is, the work functions of the first region 114a, the second region 114b and the cell gate electrode 112 may be sequentially reduced.

Although not explicitly shown, in some embodiments, the first region 114a may include a semiconductor material doped with N-type impurities, and the second region 114b may include an undoped semiconductor material. In this case, the “undoped semiconductor material” means a semiconductor material that does not include intentionally injected or doped impurities (i.e., intrinsic semiconductor material). That is, when the semiconductor material is grown, the undoped semiconductor material refers to a semiconductor material that intentionally does not inject any impurities (e.g., P-type impurities or N-type impurities) into the semiconductor layer. However, the undoped semiconductor material may include impurities diffused from an adjacent film or material layer. For example, the second region 114b may include polysilicon and N-type impurities diffused from the first region 114a.

The work function of the work function control pattern 114 may be smaller than that of the cell gate electrode 112. The work function of the undoped semiconductor material may be greater than that of the semiconductor material doped with the N-type impurities. That is, the work function of the first region 114a may be smaller than that of the second region 114b. The work function of the second region 114b may be smaller than that of the cell gate electrode 112. Therefore, the work functions of the first region 114a, the second region 114b and the cell gate electrode 112 may be sequentially increased.

The cell gate capping pattern 113 may be disposed on the cell gate electrode 112 and the work function control pattern 114. The cell gate capping pattern 113 may fill the cell gate trench 115 remaining after the cell gate electrode 112 and the work function control pattern 114 are formed. The cell gate insulating layer 111 is shown as being disposed on at least a portion of sidewalls of the cell gate capping pattern 113, but is not limited thereto.

The cell gate capping pattern 113 may include at least one of, for example, silicon nitride (SiN), silicon oxynitride (SiON), silicon oxide (SiO₂), silicon carbonitride (SiCN), silicon oxycarbonitride (SiOCN), and their combination.

In FIG. 4, the upper surface of the cell gate capping pattern 113 is shown as being coplanar with the upper surface of the cell element isolation layer 105, but is not limited thereto.

As shown in FIG. 5, an impurity doping region may be formed on at least one side of the cell gate structure 110. The impurity doping region may comprise at least a portion of a source/drain region of a transistor. The impurity doping region may be formed in the storage connection portion 103b and the bit line connection portion 103a of the exemplary semiconductor memory device shown in FIG. 2.

In FIG. 2, when a transistor, which includes each word line WL, and the bit line connecting portion 103a and the storage connecting portion 103b, which are adjacent to each word line WL, is an NMOS transistor, the storage connecting portion 103b and the bit line connecting portion 103a may include at least one of doped n-type impurities, for example, phosphorus (P), arsenic (As), antimony (Sb), and bismuth (Bi). When the transistor, which includes each word line WL, and the bit line connecting portion 103a and the storage connecting portion 103b, which are adjacent to each word line WL, is a PMOS transistor, the storage connection portion 103b and the bit line connection portion 103a may include doped P-type impurities, for example, boron (B).

The bit line structure 140ST may include a cell conductive line 140, a cell line capping layer 144, and a bit line spacer 150.

The cell conductive line 140 may be disposed on the substrate 100, on which the cell gate structure 110 is formed, and the cell element isolation layer 105. The cell conductive line 140 may cross the cell element isolation layer 105 and the cell active region ACT defined by the cell element isolation layer 105. The cell conductive line 140 may cross the cell gate structure 110. In this case, the cell conductive line 140 may correspond to the bit line BL. For example, the cell conductive line 140 may comprise at least a portion of the bit line BL shown in FIG. 1.

The cell conductive line 140 may include at least one of, for example, a semiconductor material doped with impurities, a conductive silicide compound, a conductive metal nitride, a two-dimensional (2D) material, a metal, and a metal alloy. In the semiconductor memory device according to some embodiments, the two-dimensional material may be a metallic material and/or a semiconductor material. A form of the phrase “A and/or B” as may be used herein is intended to mean “A alone, B alone, or both A and B.” The two-dimensional (2D) material may include a two-dimensional allotrope and/or a two-dimensional compound, and may include at least one of, for example, graphene, molybdenum disulfide (MoS₂), molybdenum diselenide (MoSe₂), tungsten diselenide (WSe₂) and tungsten disulfide (WS₂), but is not limited thereto. That is, since the two-dimensional materials described above are only exemplary, the two-dimensional material that may be included in the semiconductor device of the present disclosure is not limited by the above-described materials.

The cell conductive line 140 is shown as a single layer, but this is only for convenience of description and is not limited thereto. That is, unlike the shown example, the cell conductive line 140 may include a plurality of conductive layers in which conductive materials may be stacked.

The cell line capping layer 144 may be disposed on the cell conductive line 140. The cell line capping layer 144 may extend in the second direction DR2 along an upper surface of the cell conductive line 140. The cell line capping layer 144 may include at least one of, for example, a silicon nitride, silicon oxynitride, silicon carbonitride, and silicon oxycarbonitride.

In the semiconductor memory device according to some embodiments, the cell line capping layer 144 may include a silicon nitride layer. The cell line capping layer 144 is shown as a single layer, but is not limited thereto. That is, in one or more embodiments, the cell line capping layer 144 may include a plurality of material layers; two or more of the material layers may be different from each other.

The bit line spacer 150 may be disposed on sidewalls of the cell conductive line 140 and the cell line capping layer 144. The bit line spacer 150 may extend to be elongated in the second direction DR2.

The bit line spacer 150 is illustrated as a single layer, but this is only for convenience of description and is not limited thereto. That is, unlike the shown example, the bit line spacer 150 may have a multi-layered structure. The bit line spacer 150 may include one of, for example, a silicon oxide layer, a silicon nitride layer, a silicon oxynitride (SiON) layer, a silicon oxycarbonitride (SiOCN) layer, air, and their combination, but is not limited thereto.

With reference to FIGS. 3 through 6, the cell insulating layer 130 may be formed on the substrate 100 and the cell element isolation layer 105. In more detail, the cell insulating layer 130 may be formed on the upper surface of the cell element isolation layer 105 and the substrate 100 on which the bit line contact 146 and a storage contact 120 are not formed. The cell insulating layer 130 may be formed between the substrate 100 and the cell conductive line 140 and between the cell element isolation layer 105 and the cell conductive line 140.

The cell insulating layer 130 may be a single layer, but in some embodiments may comprise a multi-layer structure that includes at least a first cell insulating layer 131 and a second cell insulating layer 132. For example, the first cell insulating layer 131 may include a silicon oxide layer, and the second cell insulating layer 132 may include a silicon nitride layer, but these layers are not limited thereto. Unlike the shown example, the cell insulating layer 130 may be a triple layer that includes a silicon oxide layer, a silicon nitride layer, and a silicon oxide layer, but is not limited thereto.

The bit line contact 146 may be formed between the cell conductive line 140 and the substrate 100. The cell conductive line 140 may be disposed on the bit line contact 146.

The bit line contact 146 may be formed between the bit line connection portion 103a of the cell active region ACT and the cell conductive line 140. The bit line contact 146 may electrically connect the cell conductive line 140 with the substrate 100. The bit line contact 146 may be connected with the bit line connection portion 103a.

The bit line contact 146 may include an upper surface connected to the cell conductive line 140. A width of the bit line contact 146 in the first direction DR1 is shown as being constant as the cell conductive line 140 becomes farther away from the upper surface of the bit line contact 146, but is only for convenience of description and is not limited thereto.

The bit line contact 146 may correspond to the direct contact DC. The bit line contact 146 may include at least one of, for example, a semiconductor material doped with impurities, a conductive metal silicide, a conductive metal nitride, a conductive metal oxide, a metal, and a metal alloy.

In a portion of the cell conductive line 140, in which the bit line contact 146 may be formed, the bit line spacer 150 may be formed on the substrate 100 and the cell element isolation layer 105. The bit line spacer 150 may be disposed on sidewalls of the cell conductive line 140, the cell line capping layer 144, and the bit line contact 146.

In the other portion of the cell conductive line 140, in which the bit line contact 146 is not formed, the bit line spacer 150 may be disposed on the cell insulating layer 130. The bit line spacer 150 may be disposed on the sidewalls of the cell conductive line 140 and the cell line capping layer 144.

A fence pattern 170 may be disposed on the substrate 100 and the cell element isolation layer 105. The fence pattern 170 may overlap the substrate 100 and the cell gate structure 110 formed in the cell element isolation layer 105.

The fence pattern 170 may be between bit line structures 140ST extending in the second direction DR2. The fence pattern 170 may include at least one of, for example, silicon oxide, silicon nitride, silicon oxynitride, and their combination.

The storage contact 120 may be between the cell conductive lines 140 adjacent to each other in the first direction DR1. The storage contact 120 may be disposed at both sides of the cell conductive line 140. In more detail, the storage contact 120 may be between the bit line structures 140ST. The storage contact 120 may be between the fence patterns 170 adjacent to each other in the second direction DR2.

The storage contact 120 may overlap the substrate 100 and the cell element isolation layer 105 between the adjacent cell conductive lines 140. The storage contact 120 may be connected to the cell active region ACT. In more detail, the storage contact 120 may be connected to the storage connection portion 103b. In this case, the storage contact 120 may correspond to the buried contact BC shown in FIG. 1.

The storage contact 120 may include at least one of, for example, a semiconductor material doped with impurities, a conductive silicide compound, a conductive metal nitride, and a metal.

A storage pad 160 may be formed on the storage contact 120. The storage pad 160 may be electrically connected to the storage contact 120. The storage pad 160 may be connected to the storage connection portion 103b of the cell active region ACT. In this case, the storage pad 160 may correspond to the landing pad LP.

The storage pad 160 may overlap a portion of an upper surface of the bit line structure 140ST. The storage pad 160 may include at least one of, for example, a conductive metal nitride, a conductive metal carbide, a metal, and a metal alloy.

A pad isolation insulating layer 180 may be formed on the storage pad 160 and the bit line structure 140ST. For example, the pad isolation insulating layer 180 may be disposed on the cell line capping layer 144. The pad isolation insulating layer 180 may define at least a portion of the storage pad 160 that forms a plurality of isolation areas. The pad isolation insulating layer 180 may not cover an upper surface of the storage pad 160. For example, based on the upper surface of the substrate 100, a height of the upper surface of the storage pad 160 may be the same as that of an upper surface of the pad isolation insulating layer 180 (i.e., coplanar).

The pad isolation insulating layer 180 includes an insulating material, and may electrically isolate the plurality of storage pads 160 from each other. For example, the pad isolation insulating layer 180 may include at least one of, for example, a silicon oxide layer, a silicon nitride layer, a silicon oxynitride layer, a silicon oxycarbonitride layer, and a silicon carbonitride layer.

An etch stop layer 165 may be disposed on the upper surface of the storage pad 160 and the upper surface of the pad isolation insulating layer 180. The etch stop layer 165 may include at least one of, for example, silicon nitride (SiN), silicon carbonitride (SiCN), silicon oxycarbonitride (SiOCN), silicon oxycarbide (SiOC), and silicon boron nitride (SiBN).

The information storage element 190 may be formed on the storage pad 160. The information storage element 190 may be connected to the storage pad 160. At least a portion of the information storage element 190 may be disposed in the etch stop layer 165.

The information storage element 190 may include, for example, a capacitor, but is not limited thereto. The information storage element 190 may include a lower electrode 191, a capacitor dielectric layer 192, and an upper electrode 193. For example, the upper electrode 193 may be a plate upper electrode having a plate (e.g., rectangular) shape.

The lower electrode 191 may be disposed on the storage pad 160. The lower electrode 191 may have, for example, a pillar shape.

The capacitor dielectric layer 192 may be formed on the lower electrode 191. The capacitor dielectric layer 192 may be formed along a profile of the lower electrode 191. The upper electrode 193 may be formed on at least a portion of the capacitor dielectric layer 192. The upper electrode 193 may surround the outer wall of the lower electrode 191. The term “surround” (“surrounding” or “surrounded”) as may be used herein is intended to broadly refer to a component, structure or layer that envelops, encircles, or encloses another component, structure or layer on all sides, although breaks or gaps may also be present. Thus, for example, a material layer having voids therein may still “surround” another layer which it encircles. The upper electrode 193 is shown as a single layer, but this is only for convenience of description and is not limited thereto.

Each of the lower electrode 191 and the upper electrode 193 may include, for example, a doped semiconductor material, a conductive metal nitride (e.g., titanium nitride, tantalum nitride, niobium nitride or tungsten nitride), a metal (e.g., ruthenium, iridium, titanium or tantalum), and/or a conductive metal oxide (e.g., iridium oxide or niobium oxide), but is not limited thereto.

The capacitor dielectric layer 192 may include at least one of, for example, silicon oxide, silicon nitride, silicon oxynitride, a high dielectric constant material and their combination, but is not limited thereto. By way of example only and without limitation, in the semiconductor memory device according to some embodiments, the capacitor dielectric layer 192 may include a stacked layer structure in which zirconium oxide, aluminum oxide and zirconium oxide are sequentially stacked. In the semiconductor memory device according to some embodiments, the capacitor dielectric layer 192 may include a dielectric layer containing hafnium (Hf). In the semiconductor memory device according to some embodiments, the capacitor dielectric layer 192 may have a stacked layer structure of a ferroelectric material layer and a paraelectric material layer.

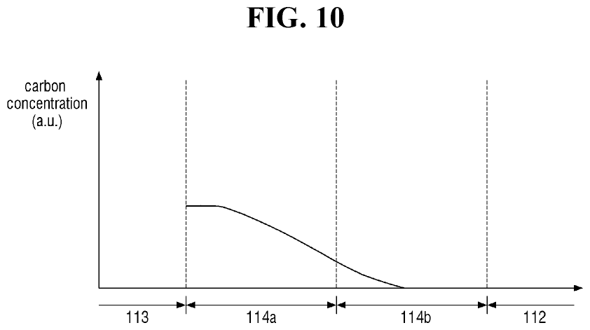

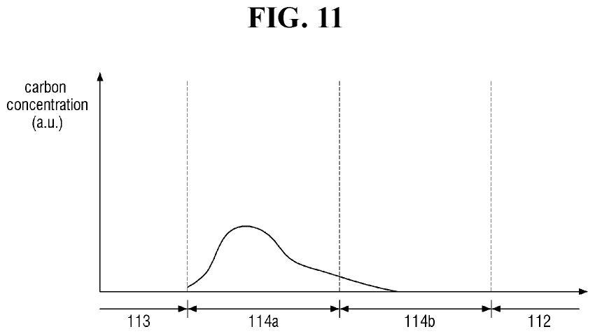

FIGS. 10 and 11 are views graphically illustrating a concentration of carbon along a line SCAN LINE in the exemplary semiconductor memory device shown in FIG. 7. For convenience purposes only and without limitation, the following description will be based on differences from the description made with reference to FIGS. 1 to 9.

Referring to FIGS. 7 and 10, in the exemplary semiconductor memory device according to some embodiments, the work function control pattern 114 may further include carbon.

In some embodiments, each of the first region 114a and the second region 114b of the work function control pattern 114 (see FIG. 7) may include carbon. The carbon may prevent impurities doped in the work function control pattern 114 from being diffused to the outside. For example, carbon doped in the work function control pattern 114 may prevent the doped N-type impurities from being diffused into surrounding material(s), outside of the work function control pattern 114, such as by heat treatment. Therefore, the concentration of impurities and the work function of each of the first region 114a and the second region 114b may be uniformly maintained.

The carbon concentration (/cm³) in the first region 114a may be greater than that in the second region 114b. The carbon concentration in the first region 114a may be the largest on the boundary surface between the first region 114a and the cell gate capping pattern 113, and may be reduced as the first region 114a becomes farther away from the cell gate capping pattern 113. In some embodiments, the carbon concentration in the second region 114b may be reduced and then converged to 0 as the second region 114b becomes farther away from the first region 114a, but is not limited thereto. Unlike the shown example, the second region 114b may not include carbon. The carbon of the work function control pattern 114 may be formed, in some embodiments, by doping the semiconductor material with carbon. The doping may be performed using a gas phase diffusion process, although embodiments of the invention are not limited thereto.

Referring to FIGS. 7 and 11, in some embodiments, each of the first region 114a and the second region 114b of the work function control pattern 114 may include carbon. The carbon may fix impurities doped into the work function control pattern 114. The carbon may reduce a work function change of each of the first region 114a and the second region 114b.

The carbon concentration (/cm³) in the first region 114a may be greater than that in the second region 114b. The carbon concentration in the first region 114a may be increased and then reduced as the first region 114a becomes farther away (in the fourth direction DR4) from the cell gate capping pattern 113. The carbon concentration of the second region 114b may be reduced and then converged to 0 as the second region 114b becomes farther away from the first region 114a. In other words, the concentration of carbon in the work function control pattern 114 may be increased to have a maximum value and then reduced in the first region 114a as the work function control pattern 114 becomes farther away from the gate capping pattern 113, but is not limited thereto. Unlike the shown example, the second region 114b may not include carbon. The carbon of the work function control pattern 114 may be formed by doping the semiconductor material with carbon. The doping may be performed using an ion implantation process, although embodiments of the invention are not limited thereto.

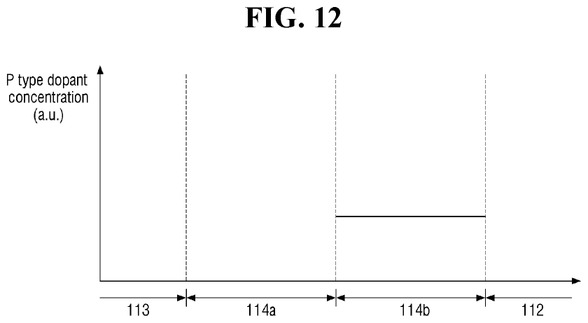

FIG. 12 is a view graphically illustrating a concentration of P-type impurities along the line SCAN LINE in the exemplary semiconductor memory device shown in FIG. 7. For convenience purposes only, the following description will be based on differences from the description made with reference to FIGS. 1 to 9.

Referring to FIGS. 7 and 12, in the semiconductor memory device according to some embodiments, the work function control pattern 114 may further include P-type impurities.

In detail, the second region 114b of the work function control pattern 114 may further include P-type impurities. The first region 114a may not include P-type impurities. The P-type impurities may be, for example, any one of boron (B) and gallium (Ga), but is not limited thereto.

The first region 114a may include N-type impurities. The description of the first region 114a may be the same as that made with reference to FIGS. 1 to 9.

In one or more embodiments, the first region 114a may include N-type impurities, and the second region 114b may include P-type impurities. Therefore, the work function of the first region 114a may be smaller than that of the second region 114b. The work function of the second region 114b may be smaller than that of the cell gate electrode 112. That is, the work functions of the first region 114a, the second region 114b and the cell gate electrode 112 may be sequentially increased.

In some embodiments, the work function control pattern 114 may further include carbon as in FIGS. 10 and 11. The description of the work function control pattern 114 may be the same as that of FIGS. 10 and 11.

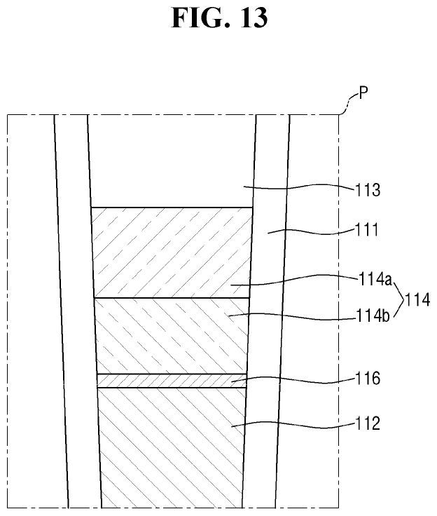

FIG. 13 is a cross-sectional view illustrating at least a portion of an exemplary semiconductor memory device according to some embodiments. For convenience purposes only, the following description will be based on differences from the description made with reference to FIGS. 1 to 9.

Referring to FIG. 13, in the semiconductor memory device according to some embodiments, the cell gate structure 110 (see FIG. 6) may further include a barrier layer 116.

The barrier layer 116 may be between the cell gate electrode 112 and the work function control pattern 114. The barrier layer 116 may cover the upper surface of the cell gate electrode 112. The barrier layer 116 may overlap the cell gate electrode 112 and the work function control pattern 114 in the fourth direction DR4.

The cell gate electrode 112 may include at least one of a metal, a metal alloy, a conductive metal nitride, a conductive metal carbonitride, a conductive metal carbide, a metal silicide, a doped semiconductor material, a conductive metal oxynitride, and a conductive metal oxide. In one or more embodiments, the cell gate electrode 112 may include, for example, titanium nitride (TiN), but is not limited thereto.

The barrier layer 116 may include at least one of a conductive metal oxynitride and a conductive metal oxide. In one or more embodiments, the barrier layer 116 may include, for example, titanium oxynitride (TiON), but is not limited thereto.

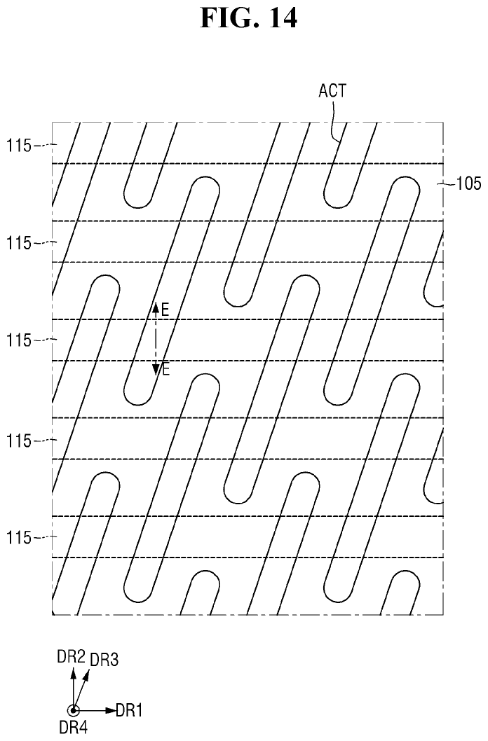

FIGS. 14 to 19 are views illustrating at least a portion of intermediate steps to describe an exemplary method for fabricating a semiconductor memory device, according to some embodiments. Portions of the description that are the same as those descriptions made with reference to the exemplary semiconductor memory device shown in FIGS. 1 to 7 will be briefly described or omitted for convenience purposes only. This does not mean, however, that such elements are omitted in the actual semiconductor memory device.

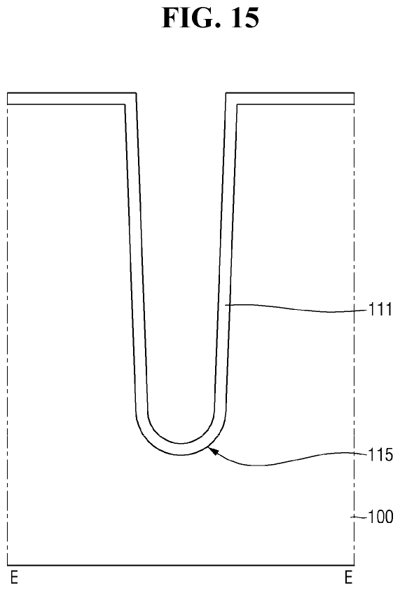

For reference, FIG. 14 is a schematic layout view illustrating a semiconductor memory device that may be formed using the exemplary method for fabricating a semiconductor memory device according to some embodiments. FIGS. 15 to 19 are cross-sectional views taken along the line E-E of FIG. 14.

Referring to FIG. 14, the cell element isolation layer 105 may be formed in the substrate 100. The cell element isolation layer 105 may have a shallow trench isolation (STI) structure having excellent element isolation characteristics, although other means for isolating adjacent active cells may be similarly contemplated. The cell element isolation layer 105 may define one or more cell active regions ACT in a memory cell area.

The cell element isolation layer 105 may include, but is not limited to, at least one of a silicon oxide layer, a silicon nitride layer and a silicon oxynitride layer.

The cell element isolation layer 105 is shown as being formed of one insulating layer, but this is only for convenience of description and is not limited thereto. The cell element isolation layer 105 may be formed of one insulating layer or a plurality of insulating layers.

Referring to FIGS. 14 and 15, the cell gate trench 115 may be formed in the substrate 100 and the cell element isolation layer 105. For example, after a mask pattern is formed on the substrate 100, the cell gate trench 115 may be formed by etching the substrate 100 using the mask pattern as an etching mask. The cell gate trench 115 may be extended in the first direction DR1. The cell gate trench 115 may be formed across the cell element isolation layer 105 and the cell active region ACT defined by the cell element isolation layer 105.

The cell gate insulating layer 111 may be formed on the upper surface of the substrate 100 and on the cell gate trench 115. The cell gate insulating layer 111 may be formed using, for example, an atomic layer deposition (ALD) process or a chemical vapor deposition (CVD) process. The cell gate insulating layer 111 may cover at least a portion of sidewalls and a bottom surface of the trench 115. The cell gate insulating layer 111 may include, but is not limited to, silicon oxide.

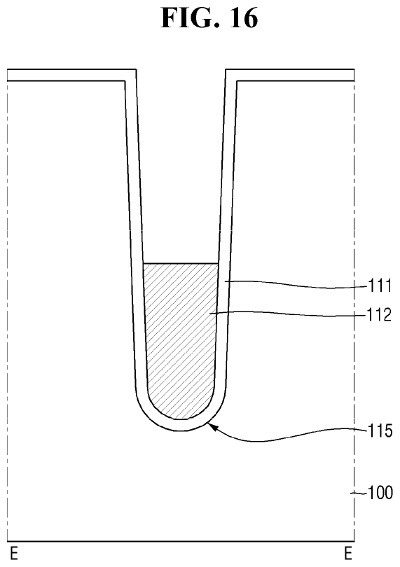

Referring to FIG. 16, the cell gate electrode 112 may be formed on at least a portion of the cell gate insulating layer 111.

A conductive material may be deposited on at least a portion of the cell gate insulating layer 111. At this time, the conductive material may at least partially fill the cell gate trench 115. The deposition of the conductive material may be performed using, for example, a chemical vapor deposition (CVD) process or the like. The conductive material may include, for example, a metal such as tungsten (W), titanium (Ti), and tantalum (Ta). Afterwards, the deposited conductive material may be etched to form the cell gate electrode 112. For example, the conductive material may be etched by an etch-back process.

The cell gate electrode 112 may include at least one of a metal, a metal alloy, a conductive metal nitride, a conductive metal carbonitride, a conductive metal carbide, a metal silicide, a doped semiconductor material, a conductive metal oxynitride, and a conductive metal oxide. The cell gate electrode 112 may include, for example, titanium nitride (TiN), but is not limited thereto.

In some embodiments, heat may be supplied to the cell gate electrode 112 after the cell gate electrode 112 is formed. In this case, the barrier layer 116 of FIG. 13 may be formed.

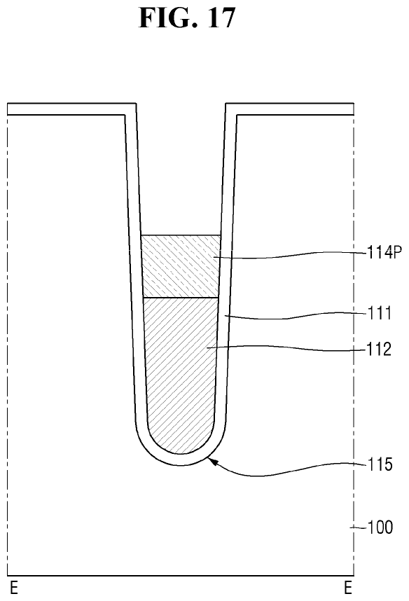

Referring now to FIG. 17, a pre-work function control pattern 114P may be formed on an upper surface of the cell gate electrode 112.

The pre-work function control pattern 114P may include a semiconductor material. The semiconductor material of the pre-work function control pattern 114P may include, for example, one of polysilicon, polysilicon-germanium, amorphous silicon, and amorphous silicon-germanium, but is not limited thereto.

For example, polysilicon may be formed on the cell gate electrode 112, and may at least partially fill the cell gate trench 115. In some embodiments, the polysilicon may be formed using a chemical vapor deposition (CVD) process or the like. The polysilicon may be etched by an etch-back process to form the pre-work function control pattern 114P.

In some embodiments, the polysilicon material forming the pre-work function control pattern 114P may be doped with N-type impurities during deposition of the polysilicon. The N-type impurities may include at least one of, for example, phosphorus (P), arsenic (As), antimony (Sb), and bismuth (Bi).

In some embodiments, in the process of depositing the polysilicon, the polysilicon may be deposited under the condition that P-type impurities are doped, and then may be deposited under the condition that N-type impurities are doped. As a result, a lower portion of the pre-work function control pattern 114P may include P-type impurities and an upper portion of the pre-work function control pattern 114P may include N-type impurities. In this case, the lower portion of the pre-work function control pattern 114P may be a portion adjacent to the cell gate electrode 112.

In some embodiments, the process of depositing the polysilicon may be performed under the condition that impurities are not doped, and then N-type impurities may be doped after deposition of the polysilicon material. As a result, the lower portion of the pre-work function control pattern 114P may include an undoped semiconductor material (e.g., polysilicon), and the upper portion of the pre-work function control pattern 114P may include N-type impurities.

Then, heat may be supplied to the pre-work function control pattern 114P. As a result, the N-type impurities doped in the pre-work function control pattern 114P may diffuse into the surrounding material outside of the pre-work function control pattern 114P, so that the concentration of the N-type impurities may be reduced.

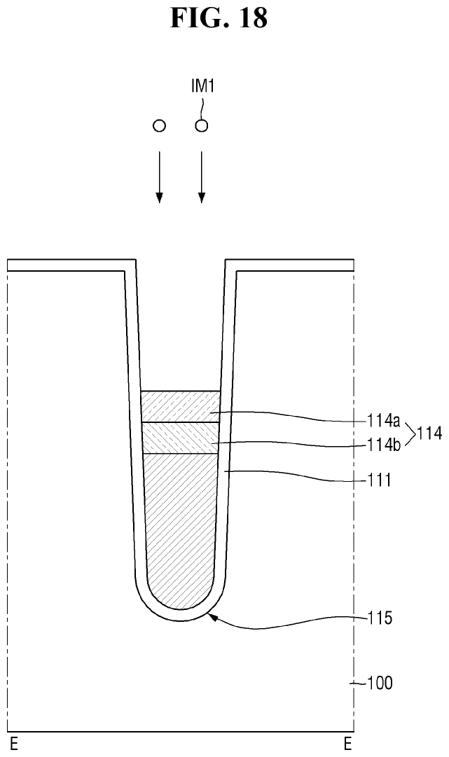

Referring to FIG. 18, the work function control pattern 114, which includes the first region 114a and the second region 114b, may be formed by doping first impurities IM1 into the pre-work function control pattern 114P. The first impurities IM1 may include at least one of, for example, phosphorus (P), arsenic (As), antimony (Sb), and bismuth (Bi).

In detail, the first impurities IM1 may be doped into or deposited on the upper surface of the pre-work function control pattern 114P exposed in the cell gate trench 115. The doping process may include, for example, a gas phase diffusion process or an ion implantation process, although embodiments of the invention are not limited thereto. The concentration of first impurities IM1 doped into the upper portion of the pre-work function control pattern 114P may be higher compared to the concentration of first impurities IM1 in the lower portion of the pre-work function control pattern 114.

In some embodiments, the first impurities IM1 and the N-type impurities doped into or deposited on the work function control pattern 114 may be the same as each other. In this case, the concentration of the N-type impurities in the first region 114a may be greater than that of the N-type impurities in the second region 114b. The concentration of the N-type impurities in the first region 114a may be 1E20(/cm³) or more. Since the concentration of the N-type impurities in the first region 114a may be greater than that of the N-type impurities in the second region 114b, the work function of the first region 114a may be smaller than that of the second region 114b.

In order to improve refresh cycle (tREF) characteristics of the semiconductor memory device, deposition of a material having a work function smaller than that of the gate electrode on the gate electrode may be required. Therefore, a semiconductor material (e.g., polysilicon) doped with impurities of a high concentration may be deposited on the gate electrode. However, the impurities doped in the semiconductor material may be diffused into the surrounding material outside of the semiconductor material by a subsequent process (e.g., etch-back process and heat treatment of the semiconductor material). That is, the concentration of impurities in the semiconductor material may be reduced.

However, as described above, in the semiconductor memory device according to some embodiments, the pre-work function control pattern 114P may be doped with the N-type impurities. As a result, the N-type impurities are maintained at a high concentration in the first region 114a of the work function control pattern 114. That is, a refresh cycle of the semiconductor memory device may be improved. The work functions of the first region 114a, the second region 114b, and the cell gate electrode 112 may be sequentially increased (e.g., as a gradient). That is, an electric field between the first region 114a and the second region 114b and between the second region 114b and the cell gate electrode 112 can be mitigated. As a result, performance of the semiconductor memory device may be improved.

Although not shown, after the doping process of the first impurities IM1, carbon may be doped in the work function control pattern 114. The concentration of carbon in the first region 114a may be higher than that in the second region 114b. The carbon may prevent impurities doped into the work function control pattern 114 from being diffused to the outside.

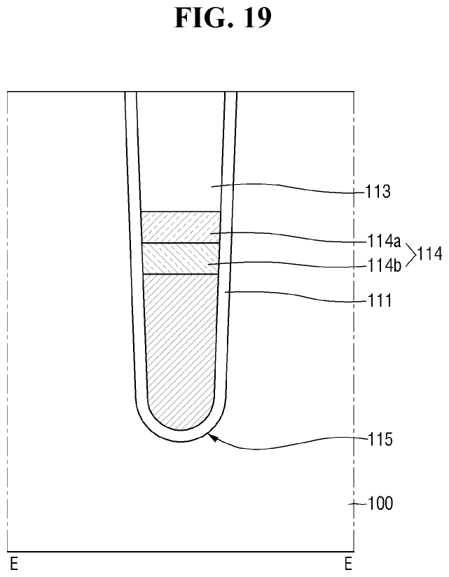

Referring to FIG. 19, the cell gate capping pattern 113 may be formed on the work function control pattern 114. The cell gate capping pattern 113 may be formed on the cell gate trench 115 having with the cell gate insulating layer 111 thereon. For example, the cell gate capping pattern 113 may be formed by forming a capping layer on an entire surface of the substrate 100 and then performing a planarization process (e.g., chemical-mechanical polishing/planarization). The cell gate capping pattern 113 may include any one of a silicon nitride layer, a silicon oxide layer, and a silicon oxynitride layer. At this time, a portion of the cell gate insulating layer 111 covering the upper surface of the substrate 100 may be removed together.

The cell gate structure 110 may be formed through the planarization process. The cell gate structure 110 may include a cell gate trench 115, a cell gate insulation layer 111, a cell gate electrode 112, a work function control pattern 114, and a cell gate capping pattern 113. The cell gate electrode 112 may correspond to the word line WL of FIGS. 8 and 9.

In some embodiments, unlike the shown example, the cell gate insulating layer 111 may remain on at least a portion of the substrate 100 even after the planarization process of the cell gate capping pattern 113. For example, the planarization process of the cell gate capping pattern 113 may be performed up to a height of the cell gate insulating layer 111 covering the upper surface of the substrate 100.

Subsequently, the bit line structure 140ST extending in the second direction DR2 may be formed on the substrate 100. The bit line structure 140ST may include a cell conductive line 140, a cell line capping layer 144, and a bit line spacer 150.

The storage contact 120, the storage pad 160, and the information storage element 190 may be formed on a second portion 103b of a cell active region ACT. The information storage element 190 may include a lower electrode 191, a capacitor dielectric layer 192, and an upper electrode 193.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Spatially descriptive terms such as “above,” “over,” “below,” “upper” and “lower” may be used herein to indicate a position of elements, structures or features relative to one another as illustrated in the figures, rather than absolute positioning. Thus, the semiconductor device may be otherwise oriented (e.g., rotated 90 degrees or at other orientations), and the spatially relative descriptions used herein may be interpreted accordingly.

It will also be understood that when an element such as a layer, region or substrate is referred to as being “atop,” “above,” “on” or “over” another element, it is broadly intended that the element be in direct contact with the other element or intervening elements can also be present. In contrast, when an element is referred to as being “directly on” or “directly over” another element, it is intended that there are no intervening elements present. Likewise, it should be appreciated that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor memory device, comprising:
a substrate including a first source/drain region and a second source/drain region;
a trench in the substrate between the first source/drain region and the second source/drain region;
a cell gate insulating layer on at least a portion of sidewalls and a bottom surface of the trench;
a cell gate electrode on at least a portion of the cell gate insulating layer;
a work function control pattern on the cell gate electrode, the work function control pattern including N-type impurities; and
a cell gate capping pattern on the work function control pattern,
wherein the work function control pattern includes a semiconductor material,
the work function control pattern includes a first region and a second region between the first region and the cell gate electrode, and
a concentration of the N-type impurities in the first region is greater than that of the N-type impurities in the second region.

2. The semiconductor memory device of claim 1, wherein a concentration of the N-type impurities in the work function control pattern is reduced as the work function control pattern becomes farther away from the cell gate capping pattern.

3. The semiconductor memory device of claim 1, wherein the concentration of the N-type impurities in the first region is increased and then decreased as the first region becomes farther away from the gate capping pattern.

4. The semiconductor memory device of claim 1, wherein the concentration of the N-type impurities in the first region is 1E20/cm³ or more.

5. The semiconductor memory device of claim 1, wherein the N-type impurities type include phosphorus.

6. The semiconductor memory device of claim 1, wherein the second region further includes P-type impurities.

7. The semiconductor memory device of claim 1, wherein the work function control pattern includes carbon.

8. The semiconductor memory device of claim 7, wherein a carbon concentration in the first region is different from a carbon concentration in the second region.

9. The semiconductor memory device of claim 1, wherein the cell gate electrode includes TiN.

10. The semiconductor memory device of claim 1, further comprising a barrier layer between the cell gate electrode and the work function control pattern.

11. The semiconductor memory device of claim 1, wherein a work function of the first region is smaller than a work function of the second region, and
the work function of the second region is smaller than a work function of the cell gate electrode.

12. A semiconductor memory device, comprising:
a substrate including an active region defined by an element isolation layer;
a bit line extending in a first direction on the substrate;
an information storage element at opposing sides of the bit line and connected to the active region; and
a cell gate structure extending in a second direction crossing the first direction in the substrate,
wherein the cell gate structure includes:
a trench in the substrate;
a cell gate insulating layer on at least a portion of sidewalls and a bottom surface of the trench;
a cell gate electrode on at least a portion of the cell gate insulating layer;
a barrier layer on at least a portion of the cell gate electrode; and
a work function control pattern on the barrier layer, the work function control pattern including a semiconductor material, and
the work function control pattern includes a first region including N-type impurities, and a second region between the first region and the cell gate electrode.

13. The semiconductor memory device of claim 12, wherein a concentration of the N-type impurities in the first region is greater than a concentration of the N-type impurities in the second region.

14. The semiconductor memory device of claim 12, wherein the second region includes an undoped semiconductor material.

15. The semiconductor memory device of claim 12, wherein the second region includes P-type impurities.

16. The semiconductor memory device of claim 12, wherein a work function of the second region is smaller than a work function of the cell gate electrode.

17. The semiconductor memory device of claim 12, wherein the work function control pattern further includes carbon, and
a concentration of carbon in the first region is greater a concentration of carbon in the second region.

18. A semiconductor memory device, comprising:
a substrate including an active region defined by an element isolation layer and extending in a first direction, the active region including a first portion and a second portion at opposing sides of the first portion;
a cell gate structure extending in a second direction in the substrate and the element isolation layer, crossing between the first portion of the active region and the second portion of the active region;
a bit line extending in a third direction on the substrate and the element isolation layer and connected to the first portion of the active region;
a storage contact at opposing sides of the bit line and connected to the second portion of the active region;
a storage pad connected to the storage contact on the storage contact; and
a capacitor connected to the storage pad on the storage pad,
wherein the cell gate structure includes:
a trench in the substrate;
a cell gate insulating layer on at least a portion of sidewalls and a bottom surface of the trench;
a cell gate electrode on at least a portion of the cell gate insulating layer;
a work function control pattern on at least a portion of the cell gate electrode, the work function control pattern including N-type impurities;
a cell gate capping pattern on at least a portion of the work function control pattern,
the work function control pattern includes a semiconductor material,
the work function control pattern includes a first region and a second region between the first region and the cell gate electrode, and
a concentration of the N-type impurities in the first region is greater than a concentration of the N-type impurities in the second region.

19. The semiconductor memory device of claim 18, wherein the work function control pattern further includes carbon, and
a concentration of carbon in the first region is greater than a concentration of carbon in the second region.

20. The semiconductor memory device of claim 18, wherein the semiconductor material includes polysilicon, and
the cell gate electrode includes TiN.
